(19) United States
(12) Patent Application Publication
(10) Pub. No.: US 2024/0394447 A1
(43) Pub. Date: Nov. 28, 2024

(54) IMAGE-BASED 3D PORE SURFACE ROUGHNESS CHARACTERIZATION METHOD

(71) Applicants: SAUDI ARABIAN OIL COMPANY, Dhahran (SA); King Abdullah University of Science and Technology, Thuwal-Jeddah (SA)

(72) Inventors: Marwah M. Alsinan, Al Qatif (SA); Yiteng Li, Thuwal (SA); Xupeng He, Thuwal (SA); Hyung Tae Kwak, Dhahran (SA); Hussein Hoteit, Thuwal (SA)

(73) Assignees: SAUDI ARABIAN OIL COMPANY, Dhahran (SA); King Abdullah University of Science and Technology, Thuwal-Jeddah (SA)

(21) Appl. No.: 18/324,806

(22) Filed: May 26, 2023

(51) Int. Cl. G06F 30/28; G06T 7/11; G06T 7/40

(52) U.S. Cl. CPC G06F 30/28; G06T 7/11; G06T 7/40; G06T 2207/10081; G06T 2207/20152; G06T 2207/30181

(57) ABSTRACT

Systems and methods for correcting NMR T2 times are disclosed. The method may include creating a plurality of 3D rough surface pore models, where each 3D rough surface pore model includes a rough surface, for each of the plurality determining a pore roughness coefficient (PRC) and a volume; and simulating a first T2 relaxation time based on the 3D rough surface pore model. The method may further include determining a smooth surface pore model, with the same volume as the 3D rough surface pore model, and simulating a second T2 relaxation time based on the smooth surface pore model. The method may still further includes determining a T2 rough surface correction factor based on the first and the second T2 relaxation times, and forming a data pair comprising the pore roughness coefficient (PRC) and the T2 rough surface correction factor; and fitting a T2 correction curve to the data pairs.

### BACKGROUND

In the petroleum industry, hydrocarbons are located in reservoirs far beneath the surface of the Earth. Wells are drilled into subsurface reservoirs to access and produce the hydrocarbons. As a wellbore is created beneath the surface of the Earth, rock core samples are often extracted and brought to the surface for examination and analysis. In conventional coring, a cylindrical section of rock is cut and removed from the path of the wellbore by a coring bit. A second coring technique, termed “sidewall coring”, may also be used to extract a rock core sample from a wellbore's sidewall rock formation. Once extracted, core samples are often examined to determine a reservoir characteristic. A reservoir characteristic may incorporate any of the characteristics pertinent to the reservoir's ability to store and produce hydrocarbons including porosity and pore size distributions. Porosity may indicate how much void space or pore space exists in a particular rock within the formation where oil, gas or water may be trapped and pore size distributions describe the relative abundance of each pore size in a particular rock.

Nuclear magnetic resonance (NMR) pore-scale simulations are techniques that assist in laboratory experiments to deeply understand reservoir characteristics. These NMR pore-scale simulations, commonly implemented by the random walk technique, simulate the physical process of magnetization decay in a three-dimensional (3D) rock core microstructure. Using NMR pore-scale simulations, the petrophysical properties of the rock may be estimated by T2 relaxation times. However, when these T2 relaxation times are used to interpret pore size distributions, regular pore shapes with smooth pore surfaces are assumed. In reality, pores in rocks exhibit rough and irregular shapes, which may lead to unreliable simulations. Improvements in pore-scale simulation techniques that correct for these rough and irregular shaped pores may aid in determining more accurate reservoir characteristics of the sample. These accurate reservoir characteristics may lead to an increased certainty of reservoir characterization and initialization.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

[to be completed upon finalization of claims]

Other aspects and advantages of the claimed subject matter will be apparent from the following description and the appended claims.

### BRIEF DESCRIPTION OF DRAWINGS

Specific embodiments disclosed herein will now be described in detail with reference to the accompanying figures. Like elements in the various figures are denoted by like reference numerals for consistency. Like elements may not be labeled in all figures for the sake of simplicity.

FIG. 1 depicts a well site in accordance with one or more embodiments.

FIG. 2A depicts a 3D rough surface pore model in accordance with one or more embodiments.

FIG. 2B depicts a shape factor distribution in accordance with one or more embodiments.

FIGS. 3A-3C depict a segmented pore image in accordance with one or more embodiments.

FIGS. 4A-4D depict 2D-cross sectional images of a pore structure in accordance with one or more embodiments.

FIGS. 5A-5C depict a 1D roughness profile in accordance with one or more embodiments.

FIG. 6 shows a T2 correction curve in accordance with one or more embodiments.

FIG. 7 shows a roughness correction graph in accordance with one or more embodiments.

FIG. 8 shows a flowchart in accordance with one or more embodiments.

FIG. 9 shows a flowchart in accordance with one or more embodiments.

FIG. 10 depicts a computer system in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

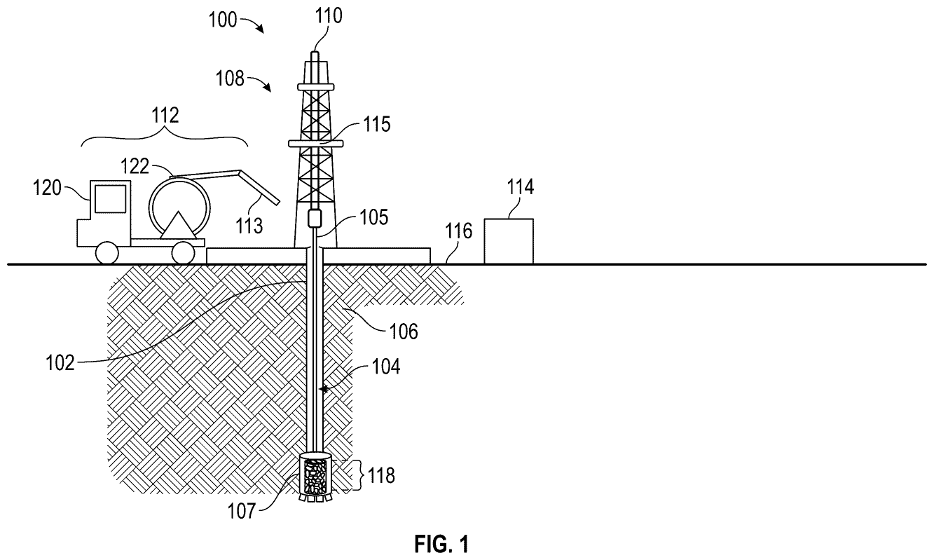

In the following description of FIGS. 1-10, any component described with regard to a figure, in various embodiments disclosed herein, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments disclosed herein, any description of the components of a figure is to be interpreted as an optional embodiment which may be implemented in addition to, in conjunction with, or in place of the embodiments described with regard to a corresponding like-named component in any other figure.

It is to be understood that the singular forms “a,” “an,” and “the” include plural referents unless the context clearly dictates otherwise. Thus, for example, reference to “a passive soil gas sample system” includes reference to one or more of such systems.

Terms such as “approximately,” “substantially,” etc., mean that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

It is to be understood that one or more of the steps shown in the flowcharts may be omitted, repeated, and/or performed in a different order than the order shown. Accordingly, the scope disclosed herein should not be considered limited to the specific arrangement of steps shown in the flowcharts.

Although multiple dependent claims are not introduced, it would be apparent to one of ordinary skill that the subject matter of the dependent claims of one or more embodiments may be combined with other dependent claims.

The embodiments disclosed herein include methods and systems to correct NMR T2 relaxation times obtained from pore-scale simulations, NMR laboratory experiments or NMR logs acquired within a wellbore. T2 relaxation times determined in NMR analyses are often underestimated, which may lead to inaccurate sample descriptions. A 3D pore surface roughness method is proposed that includes determining a correction curve characterizing a T2 correction factor for these underestimated T2 values. The method involves creating a plurality of 3D rough surface pore models having a rough surface. The 3D rough surface pore models may model the pores found in a core sample, acquired from a location along a wellbore. Creating the 3D rough surface pore models include obtaining a 3D grayscale image of a core sample, converting the 3D grayscale image into a 3D binary image, and partitioning the 3D binary image into a plurality of 3D rough surface pore models using a watershed segmentation technique. The 3D pore surface roughness method continues with determining a pore roughness coefficient (PRC) and parameterizing a correction factor for each of the 3D rough surface pore models.

Determining the PRC may involve decomposing each 3D rough surface pore model into a plurality of 2D cross-sectional images and for each 2D cross-sectional image, extracting a 1D roughness profile along a solid pore interface, discretizing the 1D roughness profile into a set of points and calculating a 1D PRC value based on a height and distance relationship between the set of points. The 1D PRC value may be averaged for each of the plurality of 2D cross-sectional images to determine the PRC for the 3D rough surface pore model. The method continues by simulating a first T2 relaxation time based on the 3D rough surface pore model, determining a smooth surface pore model that has the volume of the 3D rough surface pore model and simulating a second T2 relaxation time based on the smooth surface pore model. A T2 rough surface correction factor may be determined based on the first and second T2 relaxation times and a data pair may be formed that includes the pore roughness coefficient and the T2 rough surface correction factor. The data pair may be plotted on a T2 correction graph and a T2 correction curve may be formed describing the T2 correction factor necessary for standard NMR pore-scale simulations.

T2 values determined from traditional NMR analyses including NMR logging, NMR lab experiments, or NMR pore-scale simulations may be corrected using the T2 correction curve. The corrected T2 values may increase the accuracy to evaluate one or more reservoir characteristics of the rock sample, including porosity, pore-size distribution, fluid type, and permeability, etc. A reservoir model may be generated using a reservoir modeler, based at least in part, on the reservoir characteristics. Such reservoir models may be used to simulate the flow behavior of the reservoir fluids under different sets of circumstances and to find the optimal production techniques that will maximize production.

FIG. 1 depicts a well site (100) in accordance with one or more embodiments. The wellsite (100) may include a well (102) having a wellbore (104) extending into a rock formation (106). The wellbore (104) may include a bored hole that extends from the surface (116) into a target zone of the formation (106), such as a reservoir (not shown). The well site (100) may include a drilling system (108), a logging system (112) and a control system (114). The drilling system (108) may include a well (102) and a coring bit (107) attached by a drillstring (105) to a coring rig (110). The formation (106) may be cored to produce rock core samples (118) or core samples for analysis. Coring operations may include physically extracting a core sample (118) from a region of interest within the wellbore (104) by a coring bit (107) and bringing it to Earth's surface (116) for examination. A second coring technique, termed “sidewall coring”, may also be used to extract a core sample (118). In sidewall coring, mechanical tools may use hollow rotary drills to cut through the sidewall rock formation producing “rotary sidewall cores”.

The core samples (118), usually cylindrical, may be analyzed in a laboratory to determine various reservoir characteristics from the location from which the sample was obtained. These reservoir characteristics may include porosity, pore size distribution, permeability, or the saturation of reservoir fluids. Porosity may indicate how much void space or pore space exists in a particular rock within the formation (106), where oil, gas or water may be trapped. Pore size distribution describes the relative abundance of each pore size in a particular rock, and permeability may indicate the ability of liquids and gases to flow through the rock within the area of interest.

The wellsite (100) may include a control system (114), having hardware and/or software for managing drilling operations, logging operations and/or maintenance operations. For example, the control system (114) may include one or more programmable logic controllers (PLCs) that include hardware and/or software with functionality to control one or more processes performed by the drilling system (108). The wellsite (100) may also include a logging system (112) with one or more logging tools (113), such as a nuclear magnetic resonance (NMR) logging tool for use in generating well logs of the formation (106). Following the removal of the drilling system (108), the logging system (112) may be lowered into the wellbore (104) to acquire measurements as the tool traverses a depth interval. The plot of the logging measurements versus depth may be referred to as a “log” or “well log”. Well logs may provide depth measurements of the well (102) that describe reservoir characteristics including formation porosity, formation permeability, resistivity, water saturation, and the like. The resulting logging measurements may be stored or processed or both, for example, by a control system (114), to generate corresponding well logs for the well (102). The logging system (112) may be supported by a truck (120) and derrick (115) above ground. For example, the truck (120) may carry a conveyance mechanism (122) used to lower the logging tools (113) into the wellbore (104). The conveyance mechanism (122) may be a wireline, coiled tubing, or drill pipe that may include means to provide power to the well logging system (112) and a telemetry channel from the well logging system (112) to the surface (116). In some embodiments, the well logging system (112) may be translated along the depth of the wellbore (104) to acquire a well log over multiple depth intervals.

The logging tools (113) may include, but are not limited to acoustic logging tools, neutron logging tools, and resistivity logging tools. Thus, the well log acquired from the well logging system (112) may be an acoustic log, neutron log, or resistivity log. For the current disclosure, an NMR logging tool is given focus, which may produce an NMR log. NMR logging measures the induced magnetic moment of hydrogen nuclei (specifically, protons) contained within the fluid-filled pore space of porous media (for example, reservoir rocks). Thus, NMR logs may measure the magnetic response of fluids present in the pore spaces of the reservoir rocks. In so doing. NMR logs may measure porosity, permeability, pore size, pore-size distribution and the types of fluids present in the pore spaces. All these reservoir characteristics are pertinent for reservoir characterization.

When molecules, at an initial equilibrium state, are placed in a strong magnetic field, as in standard NMR logging techniques, the nuclei of some atoms (such as the proton forming a hydrogen 1H nucleus) will begin to behave like small magnets. If a broad spectrum of radio frequency waves is applied within the wellbore (104), or an RF pulse, the nuclei will begin to resonate at their own specific frequencies or resonant frequencies. This is called magnetic resonance and is achieved when the nuclei are irradiated with radio frequency. The RF pulse is then switched off, and the molecules return to their initial equilibrium state. A ‘relaxation time’ may be recorded based on these molecules returning to their initial equilibrium states.

An NMR log may determine spin-lattice relaxation values or a T1 signal amplitude that is measured from the buildup of magnetization along a static applied magnetic field. T1 signal values may be mainly related to pore size and viscosity. Likewise, a T1 signal may be measured using inversion recovery or saturation recovery, where the T1 signal may be characterized as the loss of resonance intensity following a pulse excitation. Furthermore, an NMR log may also provide transverse relaxation values on a T2 log, which describes the decay of an excited magnetization perpendicular to an applied magnetic field. The T2 signal may refer to the decaying time for protons to complete dephasing. Likewise, NMR measurements may be illustrated as a T2 signal amplitude versus time and determine a distribution of porosity components (i.e., a T2 distribution) as a function of their T2 times and may be referred to as T2 relaxation times. Thus, a T2 signal amplitude may be proportional to hydrogen content within a core sample and thus may determine porosity independent of the rock matrix. T2 relaxation times provide valuable information for determining both porosity and pore size distribution in core samples (118).

NMR logging, is often coupled with laboratory experiments, including NMR pore-scale simulations to improve the interpretation accuracy. NMR laboratory experiments and pore-scale simulations provide deep insights into a core sample (118) pore structure and give information regarding pore-size distribution, permeability, and fluid type. T2 measurements from a logging operation are often compared to the NMR laboratory experiments to improve the interpretation. However, interpreting T2 relaxation times often leads to underestimating the pore size, particularly when core samples have irregularly shaped pores and rough pore surfaces. Pore surface irregularity and roughness increase the surface area, which enhances the surface relaxation rate and leads to smaller T2 relaxation times. In addition to calibrating NMR logging, laboratory experiments and pore-scale simulations may be performed on core samples (118) in the absence of NMR logs, to determine reservoir characteristics from the sample (118).

Typical experiments involve measuring the surface roughness of a rock core sample (118) by measuring surface height variation on the sample surface, which is essentially measured from a 2D plane. However, real rocks have unique 3D pore structures. Roughness measured from a rock surface is not fully representative of roughness within the actual rock, especially considering the surface roughness effect for an enclosed pore space. Therefore, a 3D pore surface roughness method is presented to accurately characterize the surface roughness for 3D pore structures. By accurately modeling the 3D pore structures found in a core sample (118). T2 relaxation times from NMR pore-scale simulations may be efficiently and confidently corrected. These corrected values may help to accurately calibrate NMR logging results, thereby providing accurate reservoir characteristics.

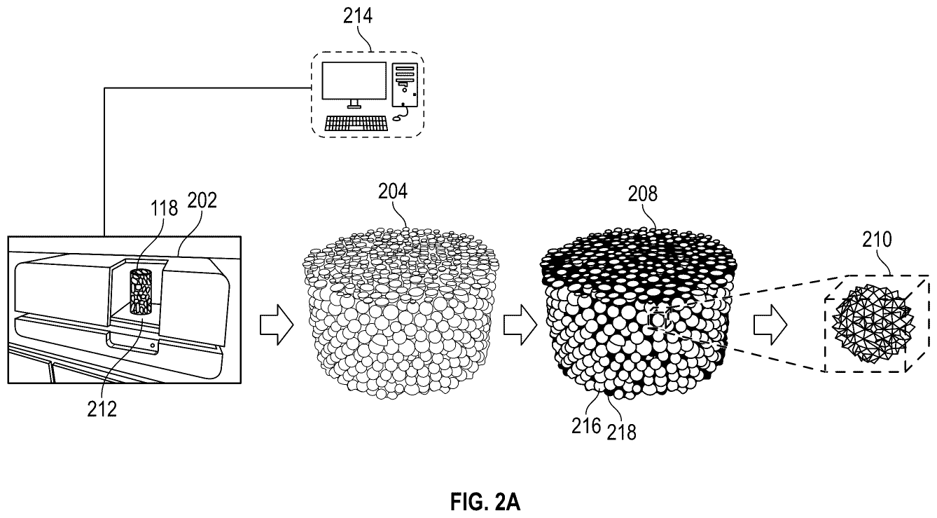

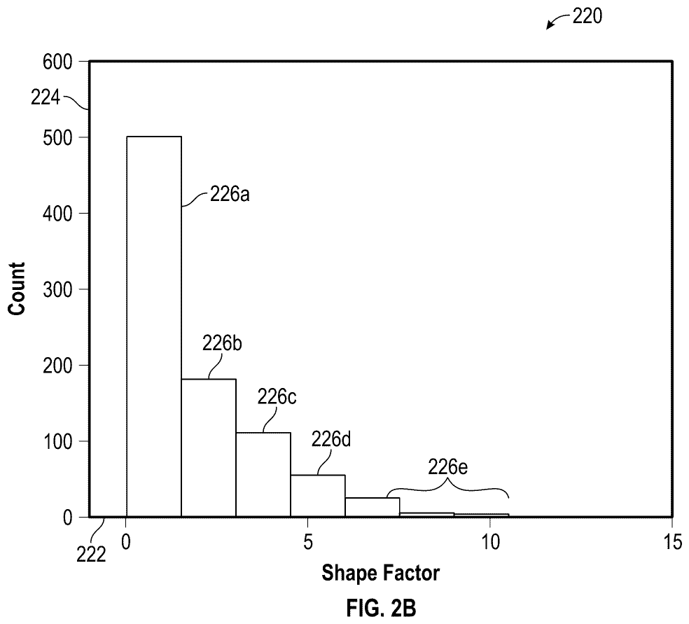

FIG. 2A depicts a 3D rough surface pore model (210), determined from a 3D grayscale image (204) of a core sample (118). The core sample (118) may be extracted from a wellsite (100) according to FIG. 1 and sent to a laboratory to evaluate the pore-scale surface roughness and its effect on NMR T2 responses. The core sample (118), or a smaller section of the core sample (118), may be placed inside the holder (212) of a micro-computed tomography (micro-CT) scanner (202) to obtain the 3D grayscale image (204). Micro-CT scanners (202) generate a 3D reconstruction of an image from a series of tomograms, which are 2D images generated by a circular X-ray sweep around the sample. The 2D images are then stacked into a cylindrical representation of the 3D sample and stitched together to form the final reconstructed 3D grayscale image (204) revealing detailed pore structure information. The micro-CT scanner (202) may be connected to a computer processor (214) capable of displaying the 3D grayscale image (204) on one or more monitors.

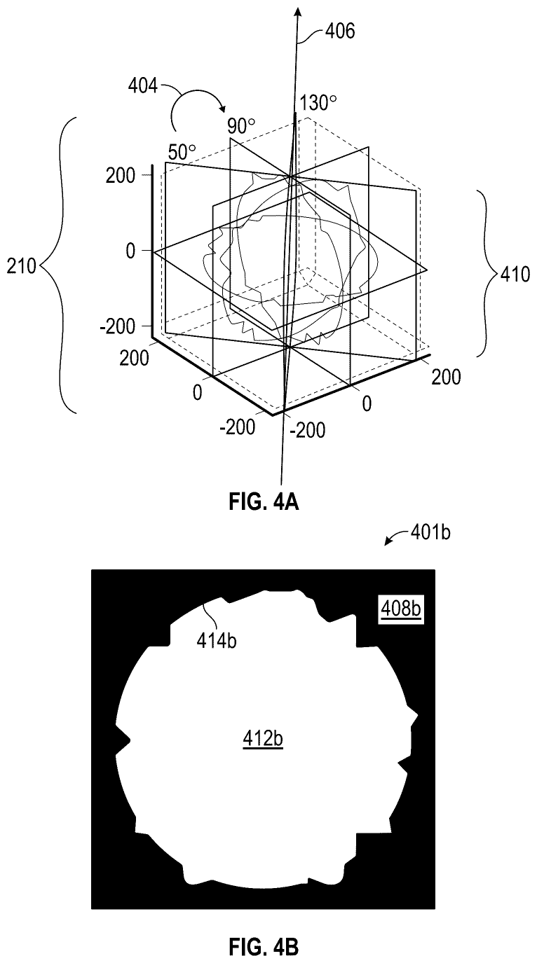

Furthermore, although the disclosure describes the grayscale and binary images being a 3D image, the 3D pore surface roughness method may also use 2D micro-CT and scanning electron microscope (SEM) thin sections in some embodiments. An SEM is a type of electron microscope that produces high-resolution images of a sample by scanning the surface with a focused beam of electrons. The electrons interact with atoms in the sample, producing various signals that contain information about the surface topography. By using an SEM, high-resolution 2D thin-section grayscale images of the sample may be generated. If 2D thin sections are used, the 3D rough surface pore model (210) would be a 2D rough surface pore model. The 2D-micro-CT thin sections are discussed below in FIGS. 4A-4D.

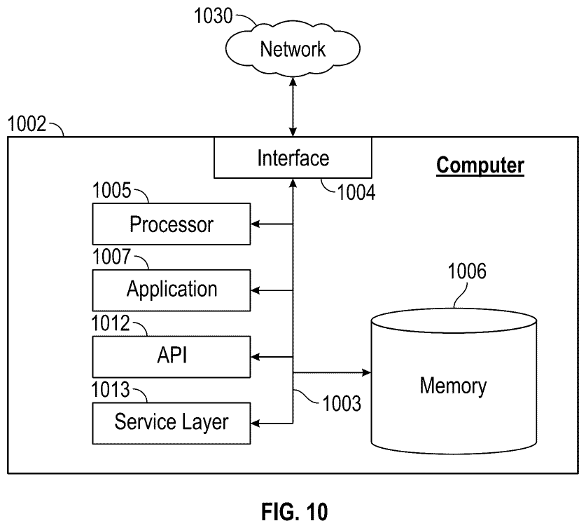

A Micro-CT scanner (202) or an SEM may be used in this method, and either may be connected to a computer processor (214). The computer processor (214) may be any microprocessor or set of microprocessors housed in a computing device such as the computer system (1002) shown in FIG. 10 and described below.

Using the computer processor (214), the 3D grayscale image (204) may be converted into a 3D binary image (208). A 3D binary image (208) is an image that consists of pixels having only one of two colors, usually black and white. Each pixel of a binary image (208) is stored as a single bit having a value of zero or one. In some embodiments, the pixels having a value of one may be represented with a white color and the pixels having a value of zero are represented with a black color, while in other embodiments the convention pay be reversed with pixels having a value of one may be represented with a black color and the pixels having a value of zero are represented with a white color. The 3D binary image (208) is shown with the pores (216) in white having a value of 1 and the non-pores or solid rock structures (218) in black having a value of zero. The solid rock structure (218) may be any non-void area of the rock surface including minerals and grain surfaces. Any suitable method known to those of ordinary skill in the art may be used to convert the 3D grayscale image (204) into the 3D binary image (208) using the computer processor (214) without deviating from the scope of the method disclosed herein.

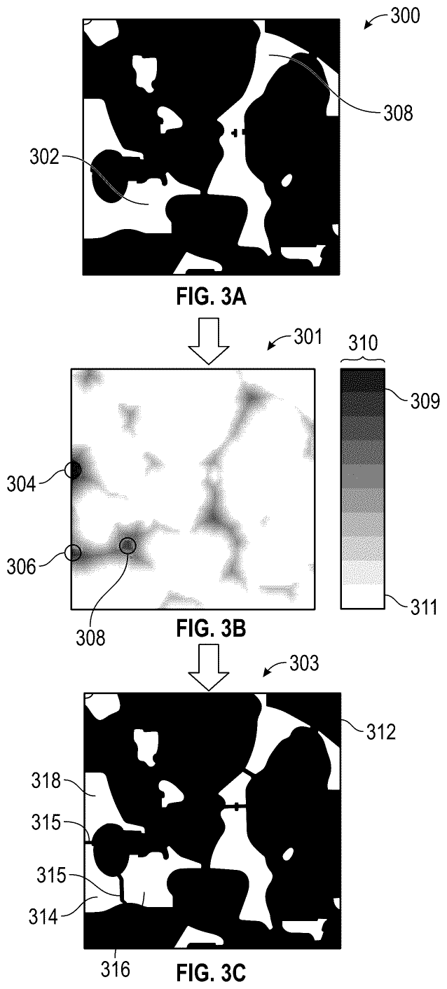

Continuing with FIG. 2A, the 3D binary image (208) may be partitioned into a plurality of 3D rough surface pore models (210) using a watershed segmentation technique. The watershed segmentation technique aims to segment the connected pore structures in the 3D binary image (208) into individual pore structures, so that they may be evaluated to determine if the sample (118) exhibits a pore-shape heterogeneity. The watershed segmentation technique is described further in FIG. 3.

With the individual pores (216) on the 3D binary image (208) now separated, a pore shape heterogeneity may be characterized by determining a distribution of shape factors (220) for the pores (216), illustrated in FIG. 2B. Shape factors are dimensionless quantities used in image analysis and microscopy techniques that numerically describe the shape of an object, in this case, the pore shape. Shape factors may be determined from the 3D binary image (208) by measuring different pore dimensions including diameter, area, volume, and perimeter. For the current method, the distribution of the dimensionless shape factor (SFᵢ) may be defined as follows:

$${SF}_{i} = \frac{{S}_{i}^{3}}{36 π {V}_{i}^{2}} \qquad Equation ( 1 )$$

where Sᵢ and Vᵢ denotes the surface area and volume of the ith pore. A wide shape factor distribution indicates a strong pore-shape heterogeneity. By using the distribution of shape factors (220), different parent pore structures may be identified.

In FIG. 2B, the shape factor is defined on the horizontal axis (222) and the vertical axis (224) defines the total number of pores (216) having the same or similar shape factor value. Using this distribution of shape factors (220), multiple parent pore structures may be identified based, at least in part, on having a similar shape factor value. For example, a separate parent pore structure may be determined for each grouping of similar shape factors, such as the groups 226a-226e. In some embodiments, shape factors at the far ends of the distributions may be grouped into a single parent pore structure classification, as shown by the group 226e. In other embodiments, each separate shape factor may be assigned a new parent pore structure. The pores (216) that are classified under each parent pore structure may share similar morphological characteristics such as a similar volume, surface volume ratio or numerical shape factor. One or more child pores may be extracted from the 3D binary image (208) representative of each parent pore structures determined. Each 3D child pore structure extracted from the 3D binary image (208) represents a 3D rough surface pore model (210) and includes the same binary pixel values as the 3D binary image (208) it was extracted from. Each 3D rough surface pore model (210) is analyzed in the subsequent steps of the 3D pore surface roughness method.

FIGS. 3A-3C depict a binary image (300) being segmented into individual pore structures (314, 316, 318) in accordance with one or more embodiments. Specifically, FIG. 3A depicts a binary image (300) which may be a 3D binary image (208) as described in FIG. 2 or a 2D binary thin section image. The binary image (300) contains interconnected pores represented as one large pore space (302) in white. The pores in the binary image (300) must be separated to classify them into different parent pore structures so that they may be accurately represented in the 3D rough surface pore models (210). The pore partitioning may be performed using a watershed segmentation technique in accordance with one or more embodiments.

The watershed segmentation technique is used in image processing to separate two touching or overlapping objects in an image and may be performed on the binary image (300) using the computer processor (214). The watershed segmentation technique begins by determining the binary image's complement. The binary image (300) has been created according to FIG. 2 with the pores (216) in white having pixel values of 1 and the solid rock structures (218) in black having pixel values of zero. To determine the complement of this image, the pixels that have a value of one will go to zero and the pixel values of zero will go to one. In the complement binary image (not shown), the pore space will now be represented with a black color corresponding to pixel values of zero, and the solid rock structures will be represented with a white color corresponding to pixel values of one. The watershed segmentation technique continues by computing a distance transform of the complement binary image. The distance transform of the complement binary image generates a distance map (301) that records the distance from every pixel to the nearest nonzero-valued pixel. In other words, the distance map (301) for a location of a zero-valued pixel, or an identified pore space, will display the distance to the nearest pore perimeter.

FIG. 3B depicts a distance map (301) calculated from the complement binary image. Using the calculated distance, the distance map (301) displays larger distances in a darker color (309) and progressively smaller distances in lighter colors according to the color bar (310). In the distance map (301), the pixels that had a value of one in the binary image (300) will have a distance of zero represented by the white color (311). In other words, this indicates that there was no distance needed to travel to a non-zero pixel and this area represents the solid rock surface (218).

Using the distance map (301), catchment basins (304, 306, 308) may be identified. A catchment basin is a geographical term describing an area of land where surface runoff water converges to a single point. Surface runoff water will naturally drain to an area that locally has the lowest elevation. In image processing, the catchment basins (304, 306, 308) describe an area with a locally low elevation, or in this case, the center of a pore. Catchment basins (304, 306, 308) are usually identified by having the smallest values on a distance map (301), therefore the distance map (301) may be negated in order to express the center of the pores as having the lowest local values. The catchment basins (304, 306, 308) may be identified automatically using a watershed algorithm in accordance with one or more embodiments. With the catchment basins (304, 306, 308) identified from the distance maps (301), a watershed ridge line (315) may be formed. A watershed is another geographical term that describes a ridge that divides areas drained by different water runoff systems. In image processing to identify individual pore structures, a watershed ridge line (315) would describe the location where two connected pores are to be separated and is illustrated in FIG. 3C on the segmented binary image (303).

This watershed segmentation technique may be implemented by a computer processor (214) using a watershed algorithm. In some embodiments, the watershed segmentation technique used may include a marker-controlled watershed transformation. In these embodiments, foreground and background markers are used to guide the segmentation process to prevent an over-segmentation. Foreground markers may be used to identify pixels or regions inside the object of interest, or in this case the pore space or catchment basins (304,306,308), while background markers may be used to identify pixels or regions outside the object of interest, or the solid rock structures (218). These foreground and background markers may be optionally used to help guide the watershed segmentation technique to assist with the pore partitioning and to avoid an over-segmentation.

Comparing the large pore space (302) to the now three individual pore structures (314, 316, 318), in the segmented binary image (303) illustrates how the watershed segmentation technique is able to successfully perform pore portioning for the 3D pore surface roughness method. Separating the connecting pore spaces into individual pore structures (314, 316, 318) may reduce the challenge of determining a surface roughness measurement for the pore space while improving the computational efficiency of the measurement.

With the pores partitioned into their individual pore structures (314, 316, 318), they may be classified into a subset of parent pore structures that share similar morphological characteristics including their shape factor. One or more child pores may be determined for each of the parent pore structures determined and they may be extracted to determine the 3D rough surface pore models (210). Each of these 3D rough surface pore models (210) is analyzed in the subsequent steps of the 3D pore surface roughness method. While the method has been described using a watershed segmentation technique, those skilled in the art will appreciate that any image segmentation method may be used to determine individual child pores from the binary image (300) without deviating from the scope of this disclosure.

FIGS. 4A-4D depict 2D cross-sectional images (401b, 401c, 401d) of a 3D rough surface pore model (210) in accordance with one or more embodiments. A direct surface roughness measurement on a 3D volume is a challenging and time-consuming task, instead the 3D pore surface roughness method uses a dimension-reduction strategy to determine the surface roughness of each 3D rough surface pore model (210). The 3D rough surface pore models (210) will be decomposed into a plurality of 2D cross-sectional images (401b, 401c, 401d) so that the surface roughness may be measured from a lower dimensional object. A rotational axis (406) is formed through the center of the 3D rough surface pore model (210) and an incremental angle (404) is determined according to the morphological features of the 3D rough surface pore model (210). The incremental angle (404) describes the number of 2D cross-sectional images (401b, 401c, 401d) that may be determined. For example, an incremental angle (404) of 10° would produce 18 cross sectional planes (410) where a 2D image may be extracted from. A 2D cross-sectional image (401b, 401c, 401d) may be extracted from each one of the cross-sectional planes (410) to evaluate a surface roughness. The number of 2D cross-sectional images (401b, 401c, 401d) should include a comprehensive sampling of the 3D rough surface pore model (210), in accordance with one or more embodiments.

In FIG. 4A three cross-sectional planes (410) are shown at 50°, 90° and 130° of the 3D rough surface pore model (210). While only three cross-sectional planes (410) are illustrated in FIG. 4A, the number of cross-sectional planes used for the 3D pore surface roughness method may be much higher and provide a comprehensive sampling of the of the 3D rough surface pore model (210). For example, in practice, an incremental angle (404) of 3° may be used producing sixty cross-sectional planes (410). A 2D cross-sectional image (401b, 401c, 401d) is extracted from each one of these three cross-sectional planes (410), as illustrated in FIGS. 4B-4D. FIG. 4A illustrates the extraction scheme for the corresponding 2D cross-sectional images (401b, 401c, 401d) and the disclosure should not be limited to the number of cross-sectional planes determined.

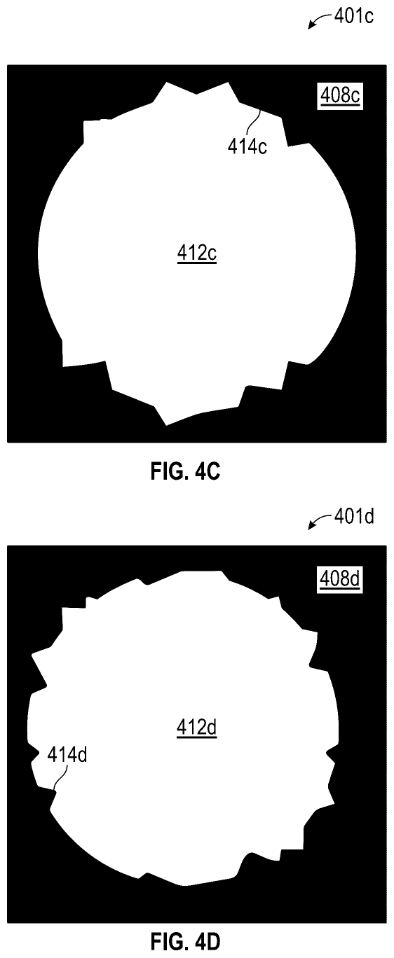

FIG. 4B shows a 2D cross-sectional image (401b) taken from a cross-sectional plane (410) of 50° and includes a pore space (412b), a solid rock structure (408b) and a solid pore interface (414b). The solid pore interface (414b) describes the outmost perimeter of the pore space (412b), where the solid rock structure (408b) and the pore space (412b) meet. Likewise, FIG. 4C shows a 2D cross-sectional image (401b) taken from a cross-sectional plane (410) of 90° and includes a pore space (412c), a solid rock structure (408c) and a solid pore interface (414c), and FIG. 4D shows cross-sectional image (401d) taken from a cross-sectional plane (410) of 130° and includes a pore space (412c), a solid rock structure (408c) and a solid pore interface (414c). In some embodiments, the cross-sectional images (401b, 401c, 401d) may be distorted and an image post-processing operation is applied to correct this distortion. The cross-sectional images (401b, 401c, 401d) could become distorted due to uneven pixel lengths. In this case, the distortion may be corrected by increasing the number of pixels along the longer side of the 2D cross sections images (401b, 401c, 401d) or by reducing the number of pixels along the shorter side. Each one of the cross-sectional images (401b, 401c, 401d) may be evaluated separately in the following steps described in FIGS. 5A-5C.

FIG. 5A shows a 2D cross-sectional image (501), determined from a 3D rough surface pore model (210) described by FIG. 4. The 2D cross-sectional image (501) will be processed to determine a pore roughness coefficient (PRC) which may represent the pore roughness for that particular 2D cross-sectional image (501).

The 2D cross-sectional image (501) is shown with a convex hull (502) surrounding the solid-pore interface (504). The convex hull (502) is divided into a plurality of line segments, controlled by an external parameter that determines the frequency of surface height measurements. The external parameter may be a user defined parameter, which controls the number of sub-line segments that define the convex hull (502). A larger external parameter produces a larger number of sub-line segments that are divided from the convex hull (502), producing a larger number of points (516) along the 1D roughness profile (511).

To quantify the surface height variation, the center (510) of each sub-line segment is identified and a perpendicular line (508) that passes through the center (510) of the sub-line segment is determined. The distance between the center (510) of the sub-line segment and the solid-pore interface (504) may then be measured, known as the roughness distance. A roughness distance may be calculated for each one of the pluralities of sub-line segments and rearranged to create the 1D roughness profile (511) seen in FIG. 5B.

FIG. 5B shows a 1D roughness profile (511) extracted from the solid-pore interface (504). Specifically, FIG. 5B includes a vertical axis (512) that describes the roughness distance and a horizontal axis (514) that describes the length of the convex hull (502) perimeter. To form the 1D roughness profile (511) the roughness distance for each line segment is plotted, shown by points (516) along the corresponding perimeter given by the horizontal axis (514). Then a 1D roughness profile line (518) may be drawn that connects the points (516) together. The 1D roughness profile (511) may be smoothed by applying a moving mean smoother inside of a window. A moving mean smoother is an image processing technique that may remove random variations that appear as coarseness in the 1D roughness profile based on a moving average of sequential pixel values inside a window. The moving mean smoother may suppress digital artifacts present in the 1D roughness profile line (518).

FIG. 5C shows the 1D roughness profile (511) discretized into a set of points (520). The number of points (520) may be a predefined parameter and should provide a much finer sampling when compared to the points (516) formed to create the 1D roughness profile line (518). A 1D roughness profile (511) will be created for each one of the 2D cross-sectional images determined.

To quantify the amount of correction needed to restore incorrect T2 values, the surface roughness must be represented as a single number for practical applications. For each 1D roughness profile (511) a 1D pore roughness coefficient (PRC) value may be calculated based on a height and distance relationship between the set of points (520). The concept of the joint roughness coefficient (JRC) from the field of fractures is used to determine the 1D PRC. JRC values have been proposed to quantitatively describe the irregular morphology or roughness of the fracture and the 1D PRC value may be calculated using each one of the set of points in the 1D roughness profile (511) by:

$$PRC = 51.16 {Z}^{0.531} - 11.44 \qquad Equation ( 2 )$$

$$Z = \sqrt{\frac{1}{L} {\sum }_{i} \frac{Δ {h}_{i}^{2}}{Δ {x}_{i}}} \qquad Equation ( 3 )$$

where Δx and Δh are the distance and height difference respectively between two neighboring points on the 1D roughness profile (511) and L is the horizontal distance between two ends of the 1D roughness profile (511), or the length of the convex hull (502). As each 1D roughness profile (511) has a PRC value, the roughness of 3D rough surface pore model (210) may be calculated by averaging all the PRC values of 1D roughness profiles (511).

Turning back to FIG. 2, a 3D rough surface pore model (210) may be extracted from the core sample (118) representative of each parent pore structure determined from the 3D binary image (208). The method presented to determine the PRC value for a single 3D rough surface pore model (210) may be repeated for each of the models determined so that each 3D rough surface pore model (210) may be represented by a single PRC value. The 3D pore surface roughness method continues by simulating a first T2 relaxation time for each of the models (210) in accordance with one or more embodiments.

A first T2 relaxation time may be simulated using a random walk simulation in accordance with one or more embodiments. NMR T2 relaxation times may be simulated from a random walk, by which ‘walkers’ that are representative of diffusing molecules that provide the NMR signal are randomly assigned to locations within the 3D rough surface pore model (210). These walkers are then allowed to diffuse through the pore space within the digital representation of the rock pore space in a random direction, providing for T2 relaxation time to be calculated. The T2 relaxation times may be used to interpret a pore size distribution of a given rock sample; however the typical methods assume regular pore shapes and smooth pore surfaces which may lead to underestimated pore size estimations. Therefore, a second NMR T2 relaxation time is simulated using a smooth surface pore model in accordance with one or more embodiments.

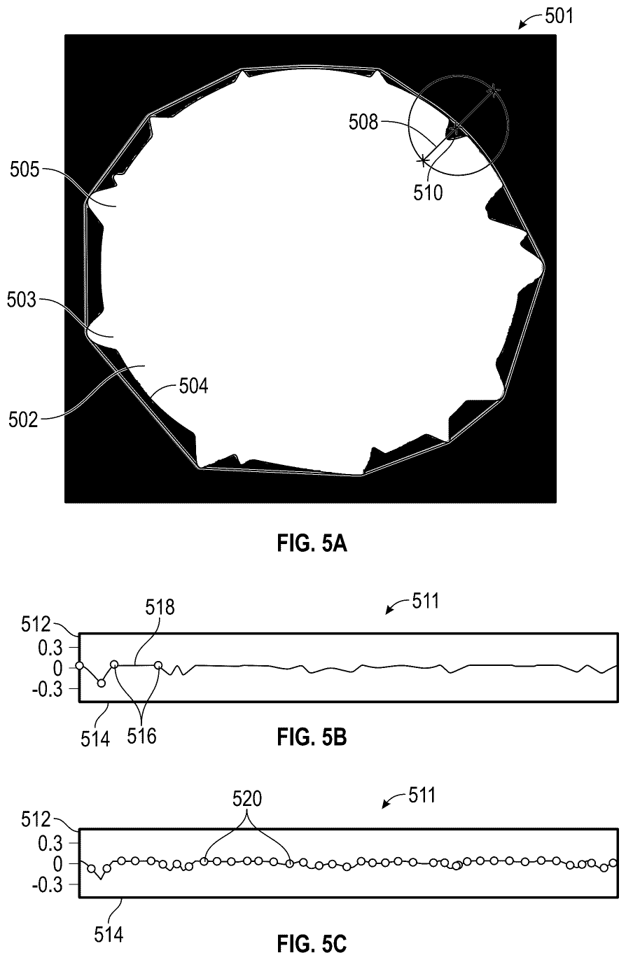

A smooth surface pore model includes the same volume as the rough surface pore models (210), and the pore boundaries includes a regular smooth shape. A volume is determined from the 3D rough surface pore model (210) and the same volume is used to determine a smooth surface pore model. Then a second T2 relaxation time is simulated using a random walk simulation. A T2 rough surface correction factor is determined by the ratio of the first T2 relaxation time over the second T2 relaxation time. This ratio of the two T2 values represents the intensity of the surface roughness effect on NMR relaxation, which may also describe the amount of correction needed to restore the underestimated T2 values back to an accurate value. This ratio, or the T2 rough surface correction factor is used to form a data pair with the PRC and is illustrated in FIG. 6.

FIG. 6 shows a T2 correction graph (600) in accordance with one or more embodiments. The T2 correction graph (600) displays a T2 rough surface correction factor on the vertical axis (602) and the PRC values on the horizontal axis (604). For each one of the 3D rough surface pore models (210), a data pair (606) is formed that includes the PRC value and the T2 rough surface correction factor. The data pair (606) is plotted on the T2 correction graph (600) and a T2 correction curve (608) is formed, which describes the correction factor for T2 values necessary for standard NMR pore-scale simulations. In future NMR analyses, a T2 relaxation times may be corrected by multiplying the T2 relaxation times by the correction factor that correlates to a determined PRC value, described on the T2 correction curve (608).

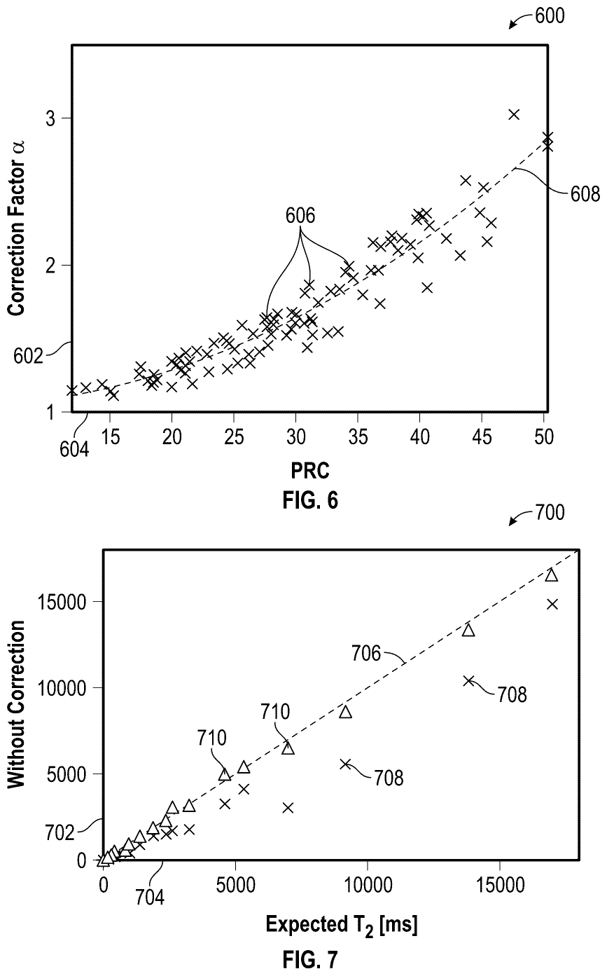

FIG. 7 shows a roughness correction graph (700) in accordance with one or more embodiments. A correlation has been determined from the T2 correction curve (608) described in FIG. 6, which may now be used to correct for T2 values in future NMR pore scale simulations. For example, turning back to FIG. 1, an NMR log may be acquired on a wellsite (100) using an NMR logging system (112). The NMR log includes a T2 measurement at a plurality of depth locations within a wellbore traversing a subsurface of the earth. A core sample (118) may also be acquired from a location along the wellbore (104) and a pore PRC value may be determined from the core sample using the 3D pore surface roughness method described herein. In order to facilitate accurate interpretation of the T2 values from NMR logging, a third T2 relaxation time may be simulated based, at least in part, on the core sample (118). The T2 values may be simulated using a random walk simulation, similar to the first and second T2 relaxation times. A T2 correction factor may then be determined based, at least in part, on the pore PRC value and the third relaxation T2 relaxation time. The third T2 relaxation time may be corrected using the T2 correction factor value and a reservoir characteristic of the core sample may then be determined based, at least in part, on the third T2 relaxation time. In some embodiments, T2 values from pore-scale simulations may be the target for the pore roughness correction. In other embodiments, an NMR log or T2 values from NMR laboratory experiments may be the target for the pore roughness correction. Furthermore, T2 values from a pore-scale simulation may be corrected using the T2 correction factor to enable accurate interpretation of an NMR log or to calibrate NMR logging equipment (113).

In FIG. 7, the roughness correction graph (700) is shown with expected T2 values for a core sample (118) displayed on the horizontal axis (704) with uncorrected T2 values from a pore-scale simulation or an NMR log on the vertical axis (702). The expected T2 values are calculated from smooth pores that honor the same volume as the determined rough surface pore model (210). The X symbols (708) on the correction graph (700) represent the measured T2 responses determined from an NMR log or pore-scale simulation. The triangle symbols (710) represent the NMR T2 responses with the T2 correction factor value applied. An NMR trend line (706) is plotted on the graph (700) to help visualize where the NMR responses should theoretically be located. It may be noticed that the majority of T2 responses without a T2 correction factor applied are located below the NMR trend line (706). This describes the problem of typical NMR T2 measurements being underestimated. In comparison, by looking at the NMR T2 responses with the T2 correction factor value applied, as described by the 3D pore surface roughness method, the triangles (710) are located much closer to the NMR trend line (706). This indicates that the 3D pore surface roughness method provides for an accurate NMR T2 relaxation time correction. Using the corrected T2 relaxation times, a reservoir characteristic may be more accurately determined, and a reservoir characterization may be more accurately defined.

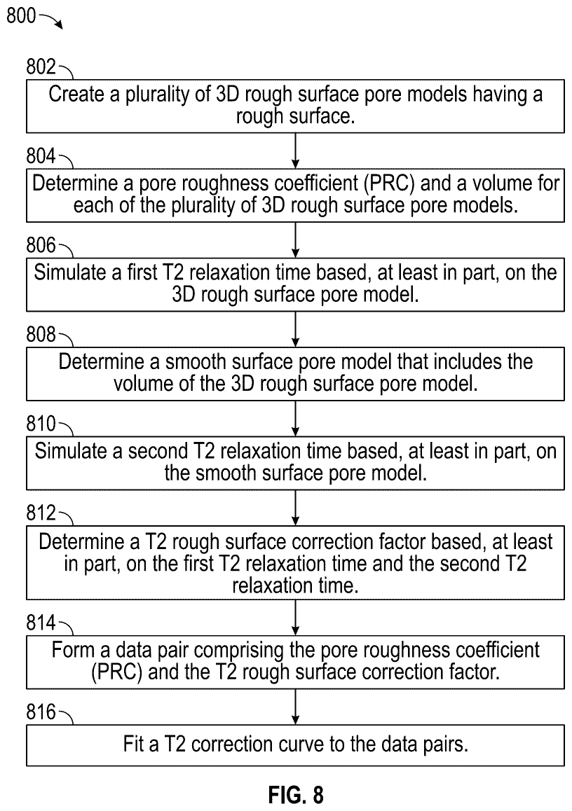

FIG. 8 shows a flowchart (800) in accordance with one or more embodiments. The flowchart (800) describes a method to generate a correction for T2 relaxation times using 3D rough surface pore models (210). T2 relaxation times determined from existing NMR pore-scale simulations often lead to underestimating the pore size, particularly when core samples have irregular pore shapes and rough pore surfaces. The 3D pore surface roughness method determines a T2 correction curve (608) that may be used to correct for these underestimated T2 relaxation times, so that accurate pore size distributions and other reservoir characteristics may be accurately determined.

In Step 802, a plurality of 3D rough surface pore models (210) may be created, having a rough surface. Creating the plurality of 3D rough surface pore models (210) may include obtaining a 3D grayscale image (204) of a core sample (118), converting the 3D grayscale image (204) into a 3D binary image (208), and partitioning the 3D binary image (208) into the plurality of 3D rough surface pore models (210) using a watershed segmentation technique. The 3D grayscale image (204) may be obtained using a micro-CT scanner (202) in some embodiments. The watershed segmentation technique to partition the 3D binary image (208) into individual pore components may aid in determining if the samples exhibit a pore-shape heterogeneity by determining a shape factor for the pores. A set of parent pore structures may be identified from the partitioned pores and one or more child pores from each of the parent pore structures identified may be extracted into a 3D rough surface pore model (210). In some embodiments, the 3D grayscale image (204) may be obtained using a micro-CT scanner using micro-computed tomography (micro-CT). In other embodiments, 2D micro-CT thin sections may be used to obtain a 2D grayscale image.

In accordance with one or more embodiments, the following Steps 804-814 are performed for each of the plurality of 3D rough surface pore models (210) described in Step 802. In Step 804, a pore roughness coefficient (PRC) and a volume may be determined. Determining the PRC may include decomposing each of the plurality of 3D rough surface pore models (210) into a plurality of 2D cross-sectional images (401b, 401c, 401d) and for each of the cross-sectional images, extracting a 1D roughness profile (511) along a solid-pore interface, discretizing the 1D roughness profile into a set of points (520), calculating a 1D PRC value based on a height and distance relationship between the set of points (520), and averaging the 1D PRC values from each of the plurality of 2D cross-sectional images (401b, 401c, 401d) to determine the PRC. Extracting the 1D roughness profile (511) may include, generating a convex hull (502) that surrounds the solid-pore interface (504) and dividing the convex hull (502) into a plurality of line segments. Then, for each of the plurality of line segments, a perpendicular line (508) may be determined that passes through the center (510) of the line segments, a roughness distance may be calculated between the center (510) of the line segment and the solid-pore interface (504), and the roughness distance may be rearranged to create the 1D roughness profile (511). The 1D roughness profile (511) may be smoothed by applying a moving mean smoother inside of a window. A moving mean smoother may suppress digital artifacts present in the 1D roughness profile line (518).

In Step 806, a first T2 relaxation time may be simulated based, at least in part, on the 3D rough surface pore model (210). The first relaxation time may be simulated using a random walk simulation. In Step 808, a smooth surface pore model may be determined, which includes the volume of the 3D rough surface pore model (210). The smooth surface pore model may be created by digitally altering a 3D rough surface pore model (210) to have a smooth pore interface and a spherical pore shape. A volume is determined from the 3D rough surface pore model (210) and the same volume is used to determine a smooth surface pore model. In Step 810, a second T2 relaxation time may be simulated based, at least in part, on the smooth surface pore model. The second relaxation time may be simulated using a random walk simulation.

In Step 812, a T2 rough surface correction factor may be determined based, at least in part, on the first T2 relaxation time and the second T2 relaxation time. The T2 rough surface correction factor is determined by the ratio of the first T2 relaxation time over the second T2 relaxation time. This ratio of the two T2 values represents the intensity of the surface roughness effect on NMR relaxation, which may also describe the amount of correction needed to restore the underestimated T2 values back to an accurate value.

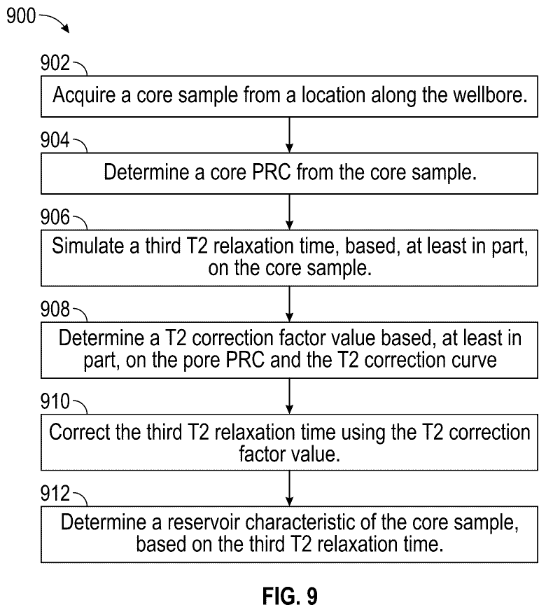

In Step 814, a data pair (606) may be formed which includes the pore roughness coefficient (PRC) and the T2 rough surface correction factor. Steps 804-814 are repeated for each of the plurality of 3D rough surface pore models (210). For each of the 3D rough surface pore models (210) created, there will be a corresponding data pair (606) that may be plotted on a T2 correction graph (600). In Step 816, a T2 correction curve (608) is fit to the data pairs. The data pair (606) may be plotted on a T2 correction graph (600) and a T2 correction curve (608) may be formed, which describes the correction factor for T2 values necessary for standard NMR pore-scale simulations. This correlation of PRC values to the rough surface correction factor, or the T2 correction curve (608) may be used in future analyses to correct for underestimated T2 values, described further by the flowchart (900) in FIG. 9. By having more accurate T2 relaxation times, reservoir characteristics such as porosity and a pore size distribution may be determined with higher confidence, aiding in hydrocarbon exploration.

FIG. 9 shows a flowchart (900) in accordance with one or more embodiments. The flowchart (900) describes a method to determine a reservoir characteristic from a core sample (118), using the T2 correction curve (608) determined from the method described in flowchart (800). In Step 902, a core sample (118) may be acquired from a location along a wellbore (104). The core sample (118) may be acquired by any technique, such as those described in FIG. 1. In Step 904, a core PRC may be determined from the core sample (118). The core PRC is determined by the same methods described in flowchart (800) to determine a PRC. In Step 906, a third T2 relaxation time is simulated based, at least in part, on the core sample. Simulating the third T2 relaxation time may be performed by any pore-scale simulation technique described herein, such as an NMR pore-scale simulation. The third T2 relaxation time simulated from such pore-scale simulators may give unreliable results needing to be corrected for. In Step 908, a T2 correction factor value may be determined based, at least in part, on the pore PRC and the T2 correction curve (608). The T2 correction curve (608), described in FIG. 6, may be used to correlate the pore PRC value with the appropriate T2 correction factor value found along the T2 correction curve (608).

In Step 910, the third T2 relaxation time is corrected using the T2 correction factor value. The T2 correction factor value may be multiplied to the third T2 relaxation times to correct for the underestimated values in accordance with one or more embodiments. These corrected T2 relaxation times accurately account for pore surface irregularity and pore surface roughness, which tend to enhance the surface relaxation rate leading to underestimated T2 values. By having more representative T2 relaxation times for a core sample (118) a reservoir characteristic may be more accurately determined.

In Step 912, a reservoir characteristic of the core sample may be determined based, at least in part, on the third T2 relaxation time. The reservoir characteristic includes porosity, pore-size distribution, permeability, fluid type, etc. While the flowchart (900) of FIG. 9 describes a method to correct T2 values obtained from pore-scale simulations on a core sample (118), T2 values from an NMR log may also be corrected using the method described herein. In other embodiments, T2 values from pore-scale simulations may be corrected to enable accurate interpretation of an NMR log or to calibrate NMR logging equipment (113).

In some embodiments, the reservoir characteristic may be used, in combination with other geologic information to generate a reservoir model, using a reservoir modeler. A reservoir simulator may include functionality for simulating the flow of fluids, including hydrocarbon fluids such as oil and gas, through the reservoir formation. The reservoir modeler may combine information determined from the reservoir characteristic, available well logs, and any other geological models available to build the reservoir model. Well logs may provide depth measurements of a well that describe reservoir features such as formation porosity, formation permeability, resistivity, water saturation, and the like. A geologic model is a spatial representation of the distribution of sediments and rocks (rock types) in the subsurface. The reservoir models may include information regarding the total hydrocarbon in place, where the hydrocarbons are located, and how effectively the hydrocarbons can potentially flow. Using the reservoir model, the recovery process of reservoir fluids may be simulated to maximize production. The simulation may be used to predict the behavior of rocks and fluid under various hydrocarbon recovery scenarios, allowing reservoir engineers to understand which recovery options offer the most advantageous hydrocarbon recovery plan for a given reservoir, thereby maximizing the wells production.

FIG. 10 depicts a block diagram of a computer system used to provide computational functionalities associated with described algorithms, methods, functions, processes, flows, and procedures as described in this disclosure, according to one or more embodiments. The illustrated computer (1002) is intended to encompass any computing device such as a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (1002) may include a computer that includes an input device, such as a keypad, keyboard, touch screen, or other devices that can accept user information, and an output device that conveys information associated with the operation of the computer (1002), including digital data, visual, or audio information (or a combination of information), or a GUI.

The computer (1002) can serve in a role as a client, network component, a server, a database or other persistency, or any other component (or a combination of roles) of a computer system for performing the subject matter described in the instant disclosure. The illustrated computer (1002) is communicably coupled with a network (1030). In some implementations, one or more components of the computer (1002) may be configured to operate within environments, including cloud-computing-based, local, global, or other environment (or a combination of environments).

At a high level, the computer (1002) is an electronic computing device operable to receive, transmit, process, store, or manage data and information associated with the described subject matter. According to some implementations, the computer (1002) may also include or be communicably coupled with an application server, e-mail server, web server, caching server, streaming data server, business intelligence (BI) server, or other server (or a combination of servers).

The computer (1002) can receive requests over network (1030) from a client application (for example, executing on another computer (1002) and responding to the received requests by processing the said requests in an appropriate software application. In addition, requests may also be sent to the computer (1002) from internal users (for example, from a command console or by other appropriate access method), external or third-parties, other automated applications, as well as any other appropriate entities, individuals, systems, or computers.

Each of the components of the computer (1002) can communicate using a system bus (1003). In some implementations, any or all of the components of the computer (1002), both hardware or software (or a combination of hardware and software), may interface with each other or the interface (1004) (or a combination of both) over the system bus (1003) using an application programming interface (API) (1012) or a service layer (1013) (or a combination of the API (1012) and service layer (1013). The API (1012) may include specifications for routines, data structures, and object classes. The API (1012) may be either computer-language independent or dependent and refer to a complete interface, a single function, or even a set of APIs. The service layer (1013) provides software services to the computer (1002) or other components (whether or not illustrated) that are communicably coupled to the computer (1002). The functionality of the computer (1002) may be accessible for all service consumers using this service layer. Software services, such as those provided by the service layer (1013), provide reusable, defined business functionalities through a defined interface. For example, the interface may be software written in JAVA, C++, or other suitable language providing data in extensible markup language (XML) format or another suitable format. While illustrated as an integrated component of the computer (1002), alternative implementations may illustrate the API (1012) or the service layer (1013) as stand-alone components in relation to other components of the computer (1002) or other components (whether or not illustrated) that are communicably coupled to the computer (1002). Moreover, any or all parts of the API (1012) or the service layer (1013) may be implemented as child or sub-modules of another software module, enterprise application, or hardware module without departing from the scope of this disclosure.

The computer (1002) includes an interface (1004). Although illustrated as a single interface (1004) in FIG. 10, two or more interfaces (1004) may be used according to particular needs, desires, or particular implementations of the computer (1002). The interface (1004) is used by the computer (1002) for communicating with other systems in a distributed environment that are connected to the network (1030). Generally, the interface (1004) includes logic encoded in software or hardware (or a combination of software and hardware) and operable to communicate with the network (1030). More specifically, the interface (1004) may include software supporting one or more communication protocols associated with communications such that the network (1030) or interface's hardware is operable to communicate physical signals within and outside of the illustrated computer (1002).

The computer (1002) includes at least one computer processor (1005). Although illustrated as a single computer processor (1005) in FIG. 10, two or more processors may be used according to particular needs, desires, or particular implementations of the computer (1002). Generally, the computer processor (1005) executes instructions and manipulates data to perform the operations of the computer (1002) and any algorithms, methods, functions, processes, flows, and procedures as described in the instant disclosure.

The computer (1002) also includes a memory (1006) that holds data for the computer (1002) or other components (or a combination of both) that can be connected to the network (1030). For example, memory (1006) can be a database storing data consistent with this disclosure. Although illustrated as a single memory (1006) in FIG. 10, two or more memories may be used according to particular needs, desires, or particular implementations of the computer (1002) and the described functionality. While memory (1006) is illustrated as an integral component of the computer (1002), in alternative implementations, memory (1006) can be external to the computer (1002).

The application (1007) is an algorithmic software engine providing functionality according to particular needs, desires, or particular implementations of the computer (1002), particularly with respect to functionality described in this disclosure. For example, application (1007) can serve as one or more components, modules, applications, etc. Further, although illustrated as a single application (1007), the application (1007) may be implemented as multiple applications (1007) on the computer (1002). In addition, although illustrated as integral to the computer (1002), in alternative implementations, the application (1007) can be external to the computer (1002).

There may be any number of computers (1002) associated with, or external to, a computer system containing computer (1002), wherein each computer (1002) communicates over network (1030). Further, the term “client,” “user,” and other appropriate terminology may be used interchangeably as appropriate without departing from the scope of this disclosure. Moreover, this disclosure contemplates that many users may use one computer (1002), or that one user may use multiple computers (1002). For example, in some embodiments, the computer processor (214) used in the 3D pore surface roughness method may perform image processing to create the 3D binary image (208) using a first computer (1002) and one or more first Applications (1007) while a T2 correction curve (608) and PRC value may be determined using a second computer (1002) using one or more second Applications (1007).

Although only a few example embodiments have been described in detail above, those skilled in the art will readily appreciate that many modifications are possible, including dimensions, in the example embodiments without materially departing from this invention. Accordingly, all such modifications are intended to be included within the scope of this disclosure as defined in the following claims.

What is claimed is:

1. A computer-implemented method, comprising:
creating a plurality of 3D rough surface pore models, wherein each 3D rough surface pore model comprises a rough surface;
for each of the plurality of 3D rough surface pore models:
determining a pore roughness coefficient (PRC) and a volume,
simulating a first T2 relaxation time based, at least in part, on the 3D rough surface pore model,
determining a smooth surface pore model, wherein the smooth surface pore model has the volume of the 3D rough surface pore model,
simulating a second T2 relaxation time based, at least in part, on the smooth surface pore model,
determining a T2 rough surface correction factor based, at least in part, on the first T2 relaxation time and the second T2 relaxation time, and
forming a data pair comprising the pore roughness coefficient (PRC) and the T2 rough surface correction factor; and
fitting a T2 correction curve to the data pairs.

2. The method of claim 1, further comprising:
acquiring a core sample from a location along a wellbore;
determining a core PRC from the core sample;
simulating a third T2 relaxation time, based, at least in part, the core sample;
determining a T2 correction factor value based, at least in part, on the core PRC and the T2 correction curve;
correcting the third T2 relaxation time using the T2 correction factor value; and
determining a reservoir characteristic of the core sample based, at least in part, on the third T2 relaxation time.

3. The method of claim 2, wherein the reservoir characteristic comprises a porosity, a pore-size distribution, a type of reservoir fluid, or a permeability.

4. The method of claim 2, further comprising:
generating a reservoir model, using a reservoir modeler based, at least in part, on the reservoir characteristic; and
simulating reservoir fluids, using the reservoir model, to maximize production.

5. The method of claim 1, wherein creating the plurality of 3D rough surface pore models comprises:
obtaining a three-dimensional (3D) grayscale image of a core sample;
converting the 3D grayscale image into a 3D binary image; and
partitioning the 3D binary image into the plurality of 3D rough surface pore models using a watershed segmentation technique.

6. The method of claim 5, wherein the 3D grayscale image is obtained using a micro-computed tomography (micro-CT) scanner.

7. The method of claim 1, wherein determining the pore roughness coefficient (PRC) comprises:
decomposing each of the plurality of 3D rough surface pore models into a plurality of 2D cross-sectional images;
for each of the plurality of 2D cross-sectional images:
extracting a 1D roughness profile along a solid-pore interface,
discretizing the 1D roughness profile into a set of points, and
calculating a 1D PRC value based on a height and distance relationship between the set of points; and
averaging the 1D PRC values from each of the plurality of 2D cross-sectional images to determine the pore roughness coefficient (PRC).

8. The method of claim 7, wherein extracting the 1D roughness profile comprises:
generating a convex hull that surrounds the solid-pore interface, wherein the convex hull comprises a plurality of line segments; and
for each of the plurality of line segments:
determining a perpendicular line that passes through a center of the line segment,
calculating a roughness distance between the center of the line segment and the solid-pore interface,
rearranging the roughness distance to create the 1D roughness profile, and
smoothing the 1D roughness profile.

9. The method of claim 8, wherein smoothing the 1D roughness profile comprises applying a moving mean smoother inside a window.

10. The method of claim 1, wherein simulating the first T2 relaxation time and the second T2 relaxation time comprises using a random walk simulation.

11. A system comprising:
a micro-computed tomography (micro-CT) scanner configured to create a 3D grayscale image of a core sample from a location along a wellbore, and
a computer processor configured to:
create a plurality of 3D rough surface pore models, wherein each pore space model comprises a rough surface,
for each of the plurality of 3D rough surface pore models:
determine a pore roughness coefficient (PRC) and a volume,
simulate a first T2 relaxation time based, at least in part, on the 3D rough surface pore model,
determine a smooth surface pore model, wherein the smooth surface pore model has the volume of the 3D rough surface pore model,
simulate a second T2 relaxation time based, at least in part, on the smooth surface pore model,
determine a T2 rough surface correction factor based, at least in part, on the first T2 relaxation time and the second T2 relaxation time, and
form a data pair comprising the pore roughness coefficient (PRC) and the T2 rough surface correction factor; and
fit a T2 correction curve to the data pairs.

12. The system of claim 11, wherein the computer processor is further configured to:
determine a core PRC from the core sample;
simulate a third T2 relaxation time, based, at least in part, the core sample;
determine a T2 correction factor value based, at least in part, on the core PRC and the T2 correction curve;
correct the third T2 relaxation time using the T2 correction factor value; and
determine a reservoir characteristic of the core sample, based at least in part, on the third T2 relaxation time.

13. The system of claim 12, wherein the reservoir characteristic comprises a porosity, a pore-size distribution, a type of reservoir fluid, or a permeability.

14. The system of claim 11, further comprising a reservoir modeler configured to produce a reservoir model based, at least in part, on the reservoir characteristic.

15. The system of claim 14, wherein the reservoir model is configured to simulate reservoir fluids to maximize production.

16. The system of claim 11, wherein the computer processor, when obtaining the plurality of 3D rough surface pore models, is configured to:
obtain a three-dimensional (3D) grayscale image of the core sample;
convert the 3D grayscale image into a 3D binary image; and
partition the 3D binary image into the plurality of 3D rough surface pore models using a watershed segmentation technique.

17. The system of claim 11, wherein the computer processor, when determining the pore roughness coefficient (PRC), is configured to:
for each of the plurality of 3D rough surface pore models:
decompose each of the plurality of 3D rough surface pore models into a plurality of 2D cross-sectional images;
for each of the plurality of 2D cross-sectional images:
extract a 1D roughness profile along a solid-pore interface,
discretize the 1D roughness profile into a set of points,
calculate a 1D PRC value based on a height and distance relationship between the set of points, and
average the 1D PRC values for each of the plurality of 2D cross-sectional images to determine the pore roughness coefficient (PRC).

18. The system of claim 17, wherein the computer processor, when extracting the 1D roughness profile along the solid-pore interface, is configured to:
generate a convex hull that surrounds the solid-pore interface, wherein the convex hull comprises a plurality of line segments; and
for each of the plurality of line segments:
determine a perpendicular line that passes through a center of the line segment,
calculate a roughness distance between the center of the line segment and the solid-pore interface,
rearrange the roughness distance to create the 1D roughness profile, and
smooth the 1D roughness profile.

19. The system of claim 18, wherein the computer processor, when smoothing the 1D roughness profile, is configured to apply a moving mean smoother inside a window.

20. The system of claim 11, wherein the computer processor, when simulating the first T2 relaxation time and the second T2 relaxation time, is configured to use a random walk simulation.
